(19) United States
(12) Patent Application Publication
(10) Pub. No.: US 2015/0176772 A1
(43) Pub. Date: Jun. 25, 2015

(54) SPHERICAL SHAPED LED ARRAY FOR AN OMNI-DIRECTIONAL LIGHT SOURCE

(71) Applicant: GE Lighting Solutions LLC, East Cleveland, OH (US)

(72) Inventors: Jeremias Anthony Martins, East Cleveland, OH (US); Monoj Ramprassad Shah, Niskayuna, NY (US); Glenn Howard Kuenzler, E. Cleveland, OH (US); Jeyachandrabose Chinniah, East Cleveland, OH (US)

(73) Assignee: GE Lighting Solutions LLC, East Cleveland, OH (US)

(21) Appl. No.: 14/136,859

(22) Filed: Dec. 20, 2013

(51) Int. Cl. F21K 99/00; H01L 25/075; H01L 33/48; H01L 33/32; H01L 33/62

(52) U.S. Cl. CPC F21K 9/30; H01L 33/32; H01L 33/62; H01L 33/486; H01L 25/0753; F21Y 2101/02

(57) ABSTRACT

Provided is a lighting system including a nonplanar surface configurable for mounting light emitting diode (LED) dies. A plurality of LED dies is mounted on the nonplanar surface. The plurality of LED dies is configured to distribute light in an omnidirectional manner.

### I. FIELD OF THE INVENTION

The present invention relates generally to light emitting diodes (LEDs). More particularly, the present invention relates to mounting LEDs on non-planar substrates.

### II. BACKGROUND

The market for LED lamps has grown exponentially as residential and commercial consumers make the change, from incandescent and halogen bulbs, to LED lighting. The typical reasons are better power efficiency and much longer lifetime. In comparison, LED lamps can easily be designed to be three to six times as efficient as incandescent and halogen bulbs. As a result, a great savings in electric energy can be realized by expanding the use of LED lamps and replacing, for example, halogen bulbs with LEDs.

A disadvantage of conventional LED lamps is that most LED arrays are mounted on a planar surface. Thus, these conventional LED lamps generally cannot produce true omnidirectional light illumination and are largely unidirectional. That is, as the light distribution angle of the light source approaches between 45° to 180°, significant losses in light production began to occur.

To create the effects of omnidirectional illumination, designers use a variety of optical beam shaping devices, such as reflectors, diffusing lens, and other ancillary devices, to bend light produced by planar LED arrays, to distribute the light in multiple directions. Light bending, however, can be extraordinarily inefficient. For example, use of the aforementioned ancillary optical devices typically results in about a 15 to 20% loss in optical efficiency.

### III. SUMMARY OF THE EMBODIMENTS

Given the aforementioned deficiencies, a need exists for methods and systems to more efficiently provide omnidirectional light distribution in LED lamps. More particularly, a need exists for methods and systems that can achieve omnidirectional light distribution in LED lamps without the need for reflectors, diffusing lens, or other largely inefficient ancillary optical devices.

In certain circumstances, an embodiment provides a lighting system including a nonplanar surface configurable for mounting light emitting diode (LED) dies. A plurality of LED dies is mounted on the nonplanar surface, wherein the nonplanar surface is affixed to a mounting platform. The plurality of LED dies is configured to distribute light in an omnidirectional manner.

Illustrious embodiments of the present invention provide a light source device formed of a nonplanar LED array. For example, LED dies, interconnected using a wire bond technique, are mounted on a hemispherical, spherical, or ellipsoid shaped thermally active substrate. In this manner, true omnidirectional light distribution can be achieved by the nonplanar LED array without the use of light bending via diffusing lens or reflectors.

Further features and advantages, as well as the structure and operation of various embodiments, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### IV. BRIEF DESCRIPTION OF THE DRAWINGS

Exemplary embodiments may take form in various components and arrangements of components. Exemplary embodiments are illustrated in the accompanying drawings, throughout which like reference numerals may indicate corresponding or similar parts in the various figures. The drawings are only for purposes of illustrating preferred embodiments and are not to be construed as limiting the invention. Given the following enabling description of the drawings, the novel aspects of the present invention should become evident to a person of ordinary skill in the art.

FIG. 1 is an illustration of a hemispherical LED light source device constructed in accordance with embodiments of the present invention.

FIG. 2 is a side view illustration of the hemispherical LED light source device illustrated in FIG. 2.

FIG. 3 is an illustration of a spherical LED light source device having LED dies mounted thereon in accordance with another embodiment of the present invention.

### V. DETAILED DESCRIPTION OF THE EMBODIMENTS

While the present invention is described herein with illustrative embodiments for particular applications, it should be understood that the invention is not limited thereto. Those skilled in the art with access to the teachings provided herein will recognize additional modifications, applications, and embodiments within the scope thereof and additional fields in which the invention would be of significant utility.

As used in this application, the terms “component”, “module”, “system”, “interface”, or the like are generally intended to refer to a computer-related entity, either hardware, a combination of hardware and software, software, or software in execution. For example, a component ay be, but is not limited to being, a process running on a processor, a processor, an object, an executable, a thread of execution, a program, and/or a computer. By way of illustration, both an application running on a controller and the controller can be a component.

Embodiments of the present invention provide an LED array configured for a true omnidirectional distribution of light. In the embodiments, a chip-on-board LED array is mounted on a nonplanar (e.g., hemispherical or spherical) shaped thermally active substrate. More particularly, LED dies chips) are mounted on the substrate, which is then positioned on a ceramic-type base. The LEDs are interconnected using a wire bonding technique, or similar, enabling electrical communication between the LEDs. This interconnectivity facilitates production of the true omnidirectional effects. Subsequently, the need for using additional and costly optical components, to bend the light, can be avoided.

In the embodiments, the LEDs can be constructed of different sizes and spaced such that omnidirectional light distribution can be optimized along with heat removal. This approach also reduces the overall power requirement. More specifically, more lumens/watt can be produced in a more environmentally friendly manner via a green light source with potentially passive cooling.

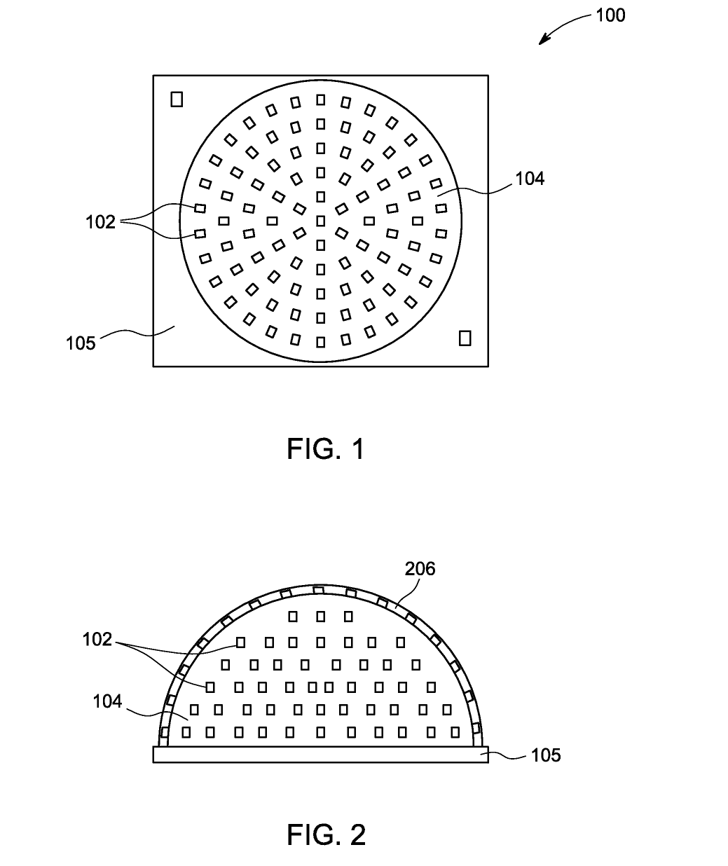

FIG. 1 is an illustration of an LED light source device 100 constructed in accordance with embodiments of the present invention. In FIG. 1, the LED light source device 100 includes a plurality of LED dies (i.e., LEDs) 102. In the embodiments, each of the LED dies 102 is formed on a silicon chip. For example, each of the dies 102 can be formed of a gallium nitride (GaN), nonpolar (n)-GaN, indium gallium nitride (InGaN), aluminum gallium nitride (AlGaN) layer based silicon, or the like.

Silicon devices of this nature have adequate long-term reliability and are efficient LED light sources. Although conventional LED dies are formed on planar substrates, embodiments of the present invention advantageously provide an approach to mount LED dies on nonplanar (e.g., hemispherical, spherical, etc.) substrates. In one example, a polygonal surface can be used. This surface can be locally flat to facilitate a single or a few LEDs at a time-virtually realizing the full benefit of a true non-planar substrate.

In the light source device 100, the LEDs 102 are fastened to a nonplanar substrate surface 104. In the embodiments, the substrate surface 104 can be spherical, hemispherical, egg shaped, or any other suitable nonplanar shape. By way of example, the LEDs 102 can be glued onto the nonplanar substrate surface 104. The substrate surface 104 can be constructed using porcelain, aluminum, or a ceramic type electrically isolating and thermally active material.

A conventional 3-dimensional axis-type machine or a 5 axis-type machine can be used, along with a three-dimensional pick and place technique, to rotate the spherical or hemispherical substrate surface 104 to facilitate mounting the LED dies 102 thereon. The LEDs 102 are mounted on the substrate surface 104, and electrically connected together, as the substrate rotates.

The LEDs 102 can be electrically connected together via wire bonding, or use of some other sophisticated flip chip technique. Wire bonding, as understood by those of skill in the art, is a technique of forming electrical interconnections on integrated circuit (IC) devices. In one wire bonding approach, for example, very fine gold wires are soldered from one LED die to another LED die to provide the electrical interconnection.

After wire bonding, the LEDs 102 can be coated with a phosphor, changing the LEDs 102 from blue light LEDs to white light LEDs. The substrate surface 104, along with the LEDs 102, is affixed to a ceramic-type platform 105.

FIG. 2 is a side view illustration of the hemispherical LED light source device 100 of FIG. 1. The LEDs 102 and the substrate surface 104 are depicted being affixed to the ceramic-type platform 105. Is also illustrated in FIG. 2, a phosphor coating 206 covers the LEDs 102.

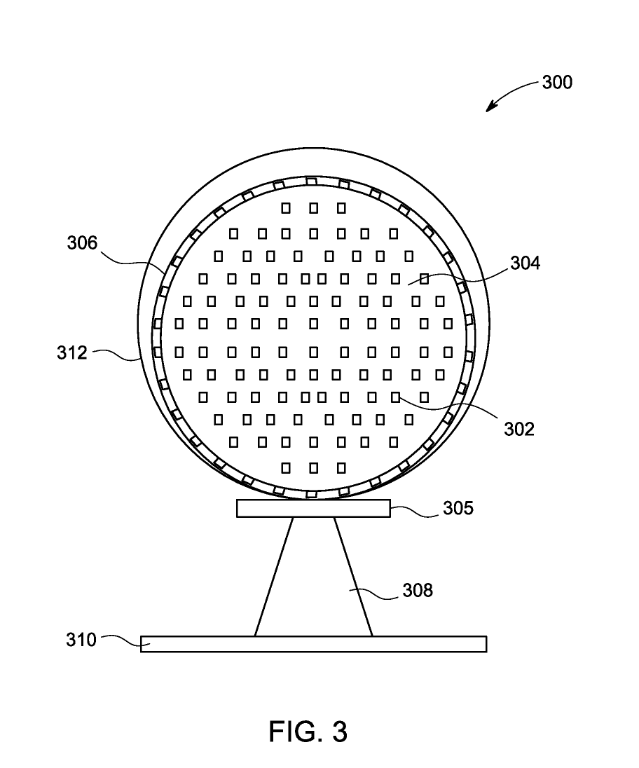

FIG. 3 is an illustration of a spherical LED light source device 300 having LED dies mounted thereon in accordance with another embodiment of the present invention. In FIG. 3, LED dies 302 are mounted onto a spherical substrate 304. The spherical substrate 304 is affixed to a ceramic-type platform 305. A phosphorus coating 306 overlays the LEDs 302.

In FIG. 3, a thermal conduit assembly 308 connects the ceramic-type platform 305 to a mounting/connection plate 310. The thermal conduit 308 also provides elevation to the LED light source device 300 facilitating an even more omnidirectional distribution of light produced by the LEDs 302. In the exemplary light source device 300, an optional veiling lens 312 is provided for glare control and ambience affects.

Also in FIG. 3, the LEDs 302 are depicted as being elevated by way of the thermal conduit 308. In other embodiments, the nonplanar LEDs 302 could be constructed in the form of a light bulb or for insertion within a lamp type device. Similarly, the light source device 300 could be a half-moon device or a ceiling light fixture where light is desirably distributed at roughly only 180′. Alternatively, the light source device 300 could be a regular light fixture or a deco light bulb for use in a chandelier, for example.

In the illustrious embodiments, a chip-on-board LED light source device is formed from a nonplanar LED array substrate. LED dies are interconnected using a wire bond technique, or similar, and are mounted on a nonplanar thermally active electrically isolating substrate. In this manner, true omnidirectional light distribution can be achieved by the nonplanar LED array without the use of complicated light bending devices, such as diffusing lens or reflectors. This type of LED light source device facilitates a direct application of phosphor to the LEDs remotely. In this remote phosphor application, the phosphor will be evenly exposed to the blue exciting LED for a more even distribution of white light.

### CONCLUSION

Alternative embodiments, examples, and modifications which would still be encompassed by the invention may be made by those skilled in the art, particularly in light of the foregoing teachings. Further, it should be understood that the terminology used to describe the invention is intended to be in the nature of words of description rather than of limitation.

Those skilled in the art will also appreciate that various adaptations and modifications of the preferred and alternative embodiments described above can be configured without departing from the scope and spirit of the invention. Therefore, it is to be understood that, within the scope of the appended claims, the invention may be practiced other than as specifically described herein.

We claim:

1. A lighting system, comprising:
a nonplanar surface;
a plurality of light emitting diode (LED) dies mounted on the nonplanar surface; and
wherein the plurality of LED dies is configured to distribute light in an omnidirectional manner.

2. The lighting system according to claim 1, wherein the nonplanar surface is spherical, hemispherical, or ellipsoid in shape.

3. The lighting system according to claim 1, wherein the dies are glued to the nonplanar surface.

4. The lighting system according to claim 1, wherein each LED die includes an LED based on at least one from the group including GaN, GaIN, and AlGaN semiconductor.

5. The lighting system according to claim 4, wherein the GaN based LED is formed of at least one of an n-GaN and an L-GaN optimized silicon layer.

6. The lighting system according to claim 1, wherein each of the dies is electrically connected to all of the other dies.

7. The lighting system according to claim 6, wherein the dies are electrically connected together via wire bonding.

8. The lighting system according to claim 1, wherein the platform is a substrate formed of at least one from the group including porcelain, aluminum, and ceramic.

9. The lighting system according to claim 1, wherein the nonplanar surface, the plurality of LEDs, and the mounting platform for a chip on board device.

10. The lighting system according to claim 1, wherein the nonplanar surface is an active substrate configured for providing electrical isolation.

11. A device comprising:
a substrate having a nonplanar surface;
wherein the substrate is configured for mounting a plurality of light emitting diode (LED) dies thereon.

12. The device of claim 11, further comprising a mounting platform configured to being affixed to the substrate.

13. The device of claim 12, wherein the platform is formed of at least one from the group including porcelain, aluminum, and ceramic.

14. The device of claim 11, wherein the plurality of LEDs is configured to produce omnidirectional light when mounted on the substrate.

15. The device of claim 11, wherein the substrate is active and configured for providing electrical isolation.
